(19) United States
(12) Patent Application Publication
(10) Pub. No.: US 2026/0371615 A1
(43) Pub. Date: Nov. 19, 2026

(54) MEMORY DEVICE HAVING A STACKED STRUCTURE OF MULTIPLE CELL WAFERS AND A PERIPHERAL WAFER

(71) Applicant: SK hynix Inc., Gyeonggi-do (KR)

(72) Inventor: Heon Yong CHANG, Gyeonggi-do (KR)

(21) Appl. No.: 19/312,301

(22) Filed: Aug. 28, 2025

(30) Foreign Application Priority Data
May 14, 2025 (KR) 10-2025-0062498

(51) Int. Cl. H10B 80/00; H10W 80/00; H10W 90/00

(52) U.S. Cl. CPC H10B 80/00; H10W 90/00; H10W 80/312; H10W 80/327; H10W 90/792

(57) ABSTRACT

Embodiments of the present disclosure provide a memory device comprising: a first wafer including a first source plate, a first memory cell array disposed below the first source plate, and a first bonding pad electrically connected to the first source plate; a second wafer bonded on the first wafer, and including a second source plate, a second memory cell array disposed on the second source plate, and a second bonding pad connected to the second source plate and bonded to the first bonding pad; and a third wafer, according to embodiments, including a peripheral circuit configured to control at least one of the first wafer and the second wafer.

### CROSS-REFERENCES TO RELATED APPLICATION

The present application claims priority under 35 U.S.C. 119(a) to Korean patent application number 10-2025-0062498 filed on May 14, 2025, which is incorporated herein by reference in its entirety.

### BACKGROUND

### 1. Technical Field

Embodiments of the present disclosure relate to semiconductor technology, and more specifically, to a memory device having a stacked structure of a plurality of cell wafers and a peripheral wafer.

### 2. Related Art

With advances in semiconductor manufacturing technology, the demand for high-performance memory is increasing, and various approaches have been proposed to meet such demand. To increase memory capacity, the number of stacked electrode layers (word lines) has increased to several hundreds of layers.

Accordingly, in the cell region, the depth of cell plugs increases, and in the peripheral circuit region, the depth of contacts increases. Such deep contact structures may cause concerns such as non-vertical etch profile, profile distortion, or disconnection due to residual insulating films. As a result, defects where electrical connection is not established may occur. Accordingly, there is a need for a solution to address concerns caused by increased contact depth resulting from the increased number of electrode layers.

### SUMMARY

Embodiments of the present disclosure provide a memory device having a stacked structure of a plurality of cell wafers and a peripheral wafer.

The objects of the embodiments of the present disclosure are not limited to those described herein, and other objects not explicitly mentioned will be clearly understood by those skilled in the art from the following description.

Embodiments of the present disclosure may provide a memory device comprising: a first wafer including a first source plate, a first memory cell array disposed below the first source plate, and a first bonding pad connected to the first source plate; a second wafer bonded on the first wafer, and including a second source plate, a second memory cell array disposed on the second source plate, and a second bonding pad connected to the second source plate and bonded to the first bonding pad; and a third wafer including a peripheral circuit configured to control at least one of the first wafer and the second wafer.

Embodiments of the present disclosure may provide a memory device comprising: a first wafer including a first source plate, a first memory cell array disposed below the first source plate, and a first bonding pad connected to the first source plate; and a second wafer bonded on the first wafer, and including a second source plate, a second memory cell array disposed on the second source plate, and a second bonding pad connected to the second source plate and bonded to the first bonding pad.

Embodiments of the present disclosure may provide a memory device comprising: a first wafer including a first source plate, a first bonding pad disposed on the first source plate and electrically connected thereto, and a first through-via below the first bonding pad; and a second wafer bonded on the first wafer, and including a second source plate and a second bonding pad electrically connected to the second source plate and bonded to the first bonding pad.

According to embodiments of the present disclosure, a memory device may be provided that has a stacked structure of a plurality of cell wafers and a peripheral wafer for distributed arrangement of memory cell arrays and sharing of source potential.

The effects of the embodiments of the present disclosure are not limited to those described above, and other effects not explicitly mentioned will be clearly understood by those skilled in the art from the description of the claims.

### BRIEF DESCRIPTION OF THE DRAWINGS

The present disclosure will be more fully understood from the following detailed description and the accompanying drawings, which are provided for illustrative purposes only and are not intended to limit the scope of the present disclosure.

FIG. 1 is a cross-sectional view of a semiconductor device according to an embodiment of the present disclosure.

FIG. 2 is a flowchart for describing a method of manufacturing the semiconductor device according to an embodiment of the present disclosure.

FIG. 3 to FIG. 17 are cross-sectional views illustrating a semiconductor device according to an embodiment of the present disclosure in the order of manufacturing steps.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc., a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc., each other via a fourth element. Here, the second element may be included in at least one of two or more elements that “are connected or coupled to”, “contact or overlap”, etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to accompanying drawings.

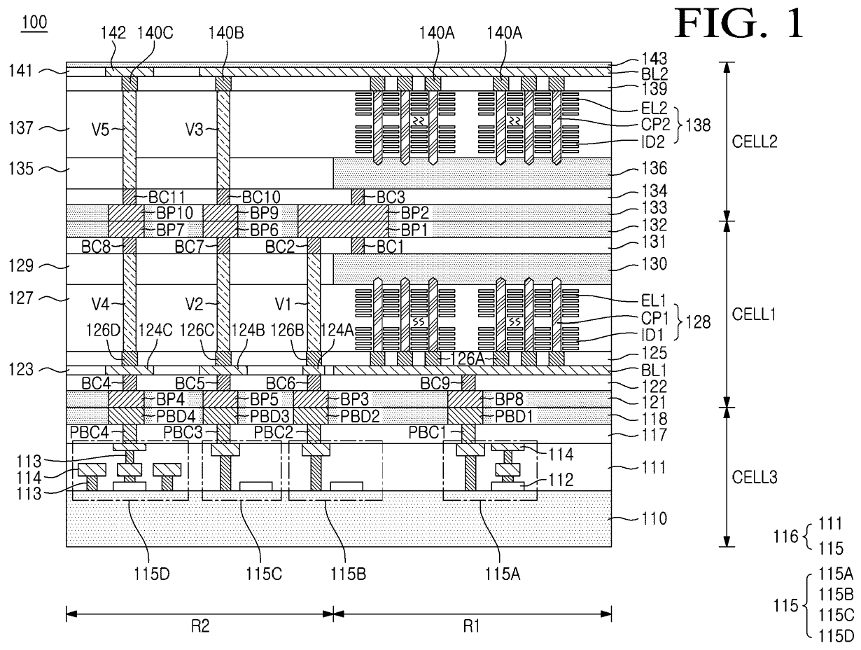

FIG. 1 is a cross-sectional view of a memory device 100 according to an embodiment of the present disclosure.

Referring to FIG. 1, the memory device 100 may include a first wafer CELL1, a second wafer CELL2, and a third wafer CELL3, stacked in a vertical direction. The first wafer CELL1 may be stacked on the third wafer CELL3, and the second wafer CELL2 may be stacked on the first wafer CELL1. The first through third wafers CELL1 to CELL3 may include a first region R1 and a second region R2 (for example, adjacent to one side of the first region R1).

The first wafer CELL1 may include a first memory cell array 128, a first source plate 130, a first bonding pad BP1, third through eighth bonding pads BP3 to BP8, first and third bonding insulating layers 132 and 121, first, second, and fourth through-vias V1, V2, and V4, first wirings 124A to 124C, a first bit line BL1, and first contacts 126A to 126D. Additionally, the first wafer CELL1 may include first and second bonding contacts BC1 and BC2, fourth through ninth bonding contacts BC4 to BC9, and first through sixth insulating layers 127, 125, 123, 122, 129, and 131.

The first insulating layer 127 is formed in the same layer as the first memory cell array 128 and may cover side surfaces of the first memory cell array 128.

The first memory cell array 128 may be disposed in the first region R1. The first memory cell array 128 may include a plurality of first cell plugs CP1 extending in a vertical direction, a plurality of first electrode layers EL1 alternately stacked along the first cell plugs CP1, and a plurality of first interlayer insulating layers ID1. At least one of the first electrode layers EL1 from an upper portion may form a source select line. At least one of the first electrode layers EL1 from a lower portion may form a drain select line. The electrode layers between the source select line and the drain select line may form word lines. The first electrode layers EL1 may include a conductive material. For example, the first electrode layers EL1 may include at least one selected from doped semiconductors (e.g., doped silicon), metals (e.g., tungsten, copper, aluminum), conductive metal nitrides (e.g., titanium nitride, tantalum nitride), or transition metals (e.g., titanium, tantalum). The first interlayer insulating layers ID1 may include silicon oxide.

Although not illustrated, each of the first cell plugs CP1 may include a channel layer and a gate insulating layer. The channel layer may include polysilicon or monocrystalline silicon, and may further include a p-type impurity such as boron (B) in a certain region. The gate insulating layer may have a straw or cylinder shell shape surrounding an outer wall of the channel layer. The gate insulating layer may include a tunnel insulating film, a charge storage film, and a blocking film sequentially stacked from the outer wall of the channel layer. In some embodiments, the gate insulating layer may have an ONO (Oxide-Nitride-Oxide) stack structure where an oxide film, a nitride film, and another oxide film are sequentially stacked. A source select transistor may be formed in portions where the source select line surrounds the first cell plugs CP1. Memory cells may be formed in portions where the word lines surround the cell plugs. A drain select transistor may be formed in portions where the drain select line surrounds the cell plugs. A drain select transistor, a plurality of memory cells, and a source select transistor arranged along one first cell plug CP1 may constitute a cell string.

The second insulating layer 125 may be disposed below the first insulating layer 127. The second insulating layer 125 may cover a bottom surface of the first insulating layer 127.

The plurality of first contacts 126A to 126D may vertically penetrate the second insulating layer 125 and be disposed in the first region R1 or the second region R2. The first contacts 126A in the first region R1 may be connected to the first cell plugs CP1. Other first contacts 126B to 126D may be formed in the same layer as the first contacts 126A and be disposed in the second region R2.

The third insulating layer 123, the first wirings 124A to 124C, and the first bit line BL1 may be disposed below the second insulating layer 125 and the first contacts 126A to 126D. The top surfaces of the third insulating layer 123, the first wirings 124A to 124C, and the first bit line BL1 may cover the bottom surfaces of the first contacts 126A to 126D and the bottom surface of the second insulating layer 125. The plurality of first wirings 124A to 124C and the first bit line BL1 may be disposed below the first contacts 126A to 126D, and the second insulating layer 125 around the first contacts 126A to 126D.

The first bit line BL1 may be disposed in the first region R1. The first contacts 126A may vertically penetrate the second insulating layer 125 and connect to the first bit line BL1. The first bit line BL1 may extend in a horizontal direction to be connected to the first contacts 126A.

The plurality of first wirings 124A to 124C may be formed in the same layer as the first bit line BL1 and may be disposed in the second region R2. The first wiring 124A may be disposed below the first contact 126B and the second insulating layer 125 around the first contact 126B. The first contact 126B may vertically penetrate the second insulating layer 125 and be connected to the first wiring 124A. The first wiring 124B may be disposed below the first contact 126C and the second insulating layer 125 around the first contact 126C. The first contact 126C may vertically penetrate the second insulating layer 125 and be connected to the first wiring 124B. The first wiring 124C may be disposed below the first contact 126D and the second insulating layer 125 around the first contact 126D. The first contact 126D may vertically penetrate the second insulating layer 125 and be connected to the first wiring 124C.

The fourth insulating layer 122 and fourth, fifth, sixth, and ninth bonding contacts BC4, BC5, BC6, and BC9 may be disposed below the third insulating layer 123, the first wirings 124A to 124C, and the first bit line BL1. The fourth insulating layer 122 and the fourth, fifth, sixth, and ninth bonding contacts BC4, BC5, BC6, and BC9 may cover the bottom surfaces of the first bit line BL1, the first wirings 124A to 124C, and the bottom surface of the third insulating layer 123. The fourth, fifth, sixth, and ninth bonding contacts BC4, BC5, BC6, and BC9 may vertically penetrate the fourth insulating layer 122 and be disposed below the first wirings 124A to 124C and the first bit line BL1.

The ninth bonding contact BC9 may be disposed in the first region R1. The ninth bonding contact BC9 may vertically penetrate the fourth insulating layer 122 and be disposed below the first bit line BL1. The ninth bonding contact BC9 may be connected to the first bit line BL1. The fourth to sixth bonding contacts BC4 to BC6 may be formed in the same layer as the ninth bonding contact BC9 and may be disposed in the second region R2. The sixth bonding contact BC6 may vertically penetrate the fourth insulating layer 122 and connect to the first wiring 124A. The fifth bonding contact BC5 may vertically penetrate the fourth insulating layer 122 and connect to the first wiring 124B. The fourth bonding contact BC4 may vertically penetrate the fourth insulating layer 122 and connect to the first wiring 124C.

The third bonding insulating layer 121 and the third, fourth, fifth, and eighth bonding pads BP3, BP4, BP5, and BP8 may be disposed below the fourth insulating layer 122 and the fourth, fifth, sixth, and ninth bonding contacts BC4, BC5, BC6, and BC9. The third bonding insulating layer 121 and the third, fourth, fifth, and eighth bonding pads BP3, BP4, BP5, and BP8 may cover the bottom surface of the fourth insulating layer 122 and the bottom surfaces of the fourth, fifth, sixth, and ninth bonding contacts BC4, BC5, BC6, and BC9. The third bonding insulating layer 121 may include a nitride.

The eighth bonding pad BP8 may be disposed in the first region R1. The ninth bonding contact BC9 may vertically penetrate the fourth insulating layer 122 and connect to the eighth bonding pad BP8. The eighth bonding pad BP8 may be connected to the first memory cell array 128 through the first contact 126A, the first bit line BL1, and the ninth bonding contact BC9 in the first region R1. The third to fifth bonding pads BP3 to BP5 may be formed in the same layer as the eighth bonding pad BP8 and may be disposed in the second region R2. The sixth bonding contact BC6 may vertically penetrate the fourth insulating layer 122 and connect to the third bonding pad BP3. The fifth bonding contact BC5 may vertically penetrate the fourth insulating layer 122 and connect to the fifth bonding pad BP5. The fourth bonding contact BC4 may vertically penetrate the fourth insulating layer 122 and connect to the fourth bonding pad BP4.

The fifth insulating layer 129 may be disposed on the first insulating layer 127. The fifth insulating layer 129 may cover an upper surface of the first insulating layer 127.

The first source plate 130 may be disposed in the first region R1. The first source plate 130 may be disposed on the first memory cell array 128 and the first insulating layer 127 around the first memory cell array 128. The first cell plugs CP1 may be connected to the first source plate 130. The first cell plugs CP1 may partially penetrate the first source plate 130. The first source plate 130 may include, for example, polysilicon, but is not limited thereto.

The first, second, and fourth through-vias V1, V2, and V4 may vertically penetrate the first insulating layer 127 and the fifth insulating layer 129 and may be disposed in the second region R2. The first through-via V1 may be connected to the first contact 126B. The first through-via V1 may be connected to the third bonding pad BP3 through the first contact 126B. The second through-via V2 may be connected to the first contact 126C. The second through-via V2 may be connected to the fifth bonding pad BP5 through the first contact 126C. The fourth through-via V4 may be connected to the first contact 126D. The fourth through-via V4 may be connected to the fourth bonding pad BP4 through the first contact 126D.

As the number of first electrode layers EL1 increases to expand memory capacity, a thickness of the first memory cell array 128 may increase. As the thickness of the first memory cell array 128 increases, a depth of the first cell plugs CP1 may also increase. An increase in the thickness of the first memory cell array 128 may also lead to an increase in the thickness of the first insulating layer 127. Accordingly, depths of the first, second, and fourth through-vias V1, V2, and V4 in the second region R2 may also increase.

The sixth insulating layer 131 may be disposed on the fifth insulating layer 129, the first source plate 130, and the first, second, and fourth through-vias V1, V2, and V4, and may cover upper surfaces of the fifth insulating layer 129, the first source plate 130, and the first, second, and fourth through-vias V1, V2, and V4.

The first bonding contact BC1 may vertically penetrate the sixth insulating layer 131 and may be connected to the first source plate 130. The second bonding contact BC2 may vertically penetrate the sixth insulating layer 131 and may be connected to the first through-via V1. The seventh bonding contact BC7 may vertically penetrate the sixth insulating layer 131 and may be connected to the second through-via V2. The eighth bonding contact BC8 may vertically penetrate the sixth insulating layer 131 and may be connected to the fourth through-via V4.

The first bonding insulating layer 132 and the first, sixth, and seventh bonding pads BP1, BP6, and BP7 may be disposed on the sixth insulating layer 131 and the first, second, seventh, and eighth bonding contacts BC1, BC2, BC7, and BC8. The first bonding insulating layer 132 and the first, sixth, and seventh bonding pads BP1, BP6, and BP7 may cover an upper surface of the sixth insulating layer 131 and the first, second, seventh, and eighth bonding contacts BC1, BC2, BC7, and BC8. The first bonding insulating layer 132 may include a nitride.

The first bonding pad BP1 may be connected to the first and second bonding contacts BC1 and BC2. The first bonding pad BP1 may be horizontally extended from the first region R1 to the second region R2 so as to be in contact with both the first and second bonding contacts BC1 and BC2. One side of the first bonding pad BP1 may horizontally protrude further toward the second region R2 than one side of the first source plate 130. The first bonding pad BP1 may be connected to the first source plate 130 through the first bonding contact BC1. The first bonding pad BP1 may be connected to the third bonding pad BP3 through the second bonding contact BC2 and the first through-via V1. The sixth and seventh bonding pads BP6 and BP7 may be formed in the same layer as the first bonding pad BP1 and may be disposed in the second region R2. The sixth bonding pad BP6 may be connected to the seventh bonding contact BC7. The sixth bonding pad BP6 may be connected to the fifth bonding pad BP5 through the seventh bonding contact BC7 and the second through-via V2. The seventh bonding pad BP7 may be connected to the eighth bonding contact BC8. The seventh bonding pad BP7 may be connected to the fourth bonding pad BP4 through the eighth bonding contact BC8 and the fourth through-via V4.

The second wafer CELL2 may include a second memory cell array 138, a second source plate 136, second, ninth, and tenth bonding pads BP2, BP9, and BP10, the second bonding insulating layer 133, third and fifth through-vias V3 and V5, a second wiring 142, a second bit line BL2, and second contacts 140A to 140C. In addition, the second wafer CELL2 may include third, tenth, and eleventh bonding contacts BC3, BC10, and BC11, the seventh to eleventh insulating layers 137, 139, 141, 135, and 134, and an upper insulating layer 143.

The seventh insulating layer 137 may be formed in the same layer as the second memory cell array 138 and may cover side surfaces of the second memory cell array 138.

The second memory cell array 138 may be disposed in the first region R1. The second memory cell array 138 may include a plurality of second cell plugs CP2 extending in a vertical direction, a plurality of second electrode layers EL2 alternately stacked along the second cell plugs CP2, and a plurality of second interlayer insulating layers ID2. Although not shown, each of the second cell plugs CP2 may include a channel layer and a gate insulating layer. The second memory cell array 138 may have substantially the same structure as the first memory cell array 128.

The eighth insulating layer 139 may be disposed on the seventh insulating layer 137. The eighth insulating layer 139 may cover the upper surface of the seventh insulating layer 137.

The plurality of second contacts 140A to 140C may vertically penetrate the eighth insulating layer 139 and may be disposed in the first region R1 or the second region R2. The second contacts 140A in the first region R1 may be connected to the second cell plugs CP2. Other second contacts 140B and 140C may be formed in the same layer as the second contacts 140A and may be disposed in the second region R2.

The ninth insulating layer 141, the second bit line BL2, and the second wiring 142 may be disposed on the eighth insulating layer 139 and the plurality of second contacts 140A to 140C. The ninth insulating layer 141, the second bit line BL2, and the second wiring 142 may cover the upper surface of the eighth insulating layer 139 and the second contacts 140A to 140C. The second wiring 142 and the second bit line BL2 may be disposed on the second contacts 140A to 140C and on the eighth insulating layer 139 around the second contacts 140A to 140C.

The second bit line BL2 may be disposed on the second contacts 140A and 140B. The second contacts 140A and 140B may vertically penetrate the eighth insulating layer 139 and may be connected to the second bit line BL2. The second bit line BL2 may be horizontally extended from the first region R1 to the second region R2 so as to be connected to the second contacts 140A and 140B.

The second wiring 142 may be formed in the same layer as the second bit line BL2 and may be disposed in the second region R2. The second wiring 142 may be disposed on the second contact 140C and on the eighth insulating layer 139 around the second contact. The second wiring 142 may be connected to the second contact 140C.

The tenth insulating layer 135 may be disposed below the seventh insulating layer 137. The tenth insulating layer 135 may cover a lower surface of the seventh insulating layer 137.

The second source plate 136 may be disposed in the first region R1. The second source plate 136 may be disposed below the second memory cell array 138 and the seventh insulating layer 137 around the second memory cell array 138. The second cell plugs CP2 may be connected to the second source plate 136. The second cell plugs CP2 may partially penetrate the second source plate 136. The second source plate 136 may have substantially the same structure as the first source plate 130.

The third and fifth through-vias V3 and V5 may vertically penetrate the seventh insulating layer 137 and the tenth insulating layer 135 and may be disposed in the second region R2. The third through-via V3 may be connected to the second contact 140B. The third through-via V3 may be disposed to vertically overlap with the second through-via V2 of the first wafer CELL1. The third through-via V3 may be connected to the second memory cell array 138 through the second contact 140B and the second bit line BL2. The fifth through-via V5 may be connected to the second contact 140C. The fifth through-via V5 may be disposed to vertically overlap with the fourth through-via V4 of the first wafer CELL1. The fifth through-via V5 may be connected to the second wiring 142 through the second contact 140C.

As the thickness of the second memory cell array 138 increases, the depth of the second cell plugs CP2 may increase. As the thickness of the second memory cell array 138 increases, the thickness of the seventh insulating layer 137 may also increase. Accordingly, the depths of the third and fifth through-vias V3 and V5 in the second region R2 may increase.

The eleventh insulating layer 134 may be disposed below the tenth insulating layer 135, the second source plate 136, and the third and fifth through-vias V3 and V5, and may cover bottom surfaces of the tenth insulating layer 135, the second source plate 136, and the bottom portions of the third and fifth through-vias V3 and V5.

The third bonding contact BC3 may vertically penetrate the eleventh insulating layer 134 and may be connected to the second source plate 136. The tenth bonding contact BC10 may vertically penetrate the eleventh insulating layer 134 and may be connected to the third through-via V3. The eleventh bonding contact BC11 may vertically penetrate the eleventh insulating layer 134 and may be connected to the fifth through-via V5.

The second bonding insulating layer 133 and the second, ninth, and tenth bonding pads BP2, BP9, and BP10 may be disposed below the eleventh insulating layer 134 and the third, tenth, and eleventh bonding contacts BC3, BC10, and BC11. The second bonding insulating layer 133 and the second, ninth, and tenth bonding pads BP2, BP9, and BP10 may cover the lower surface of the eleventh insulating layer 134 and the bottom portions of the third, tenth, and eleventh bonding contacts BC3, BC10, and BC11. The second bonding insulating layer 133 may include a nitride.

The second bonding pad BP2 may be connected to the third bonding contact BC3. The second bonding pad BP2 may be horizontally extended from the first region R1 to the second region R2. The width of the second bonding pad BP2 may be substantially equal to the width of the first bonding pad BP1. One side of the second bonding pad BP2 may horizontally protrude further toward the second region R2 than one side of the second source plate 136. In accordance with an embodiment of the present disclosure, one side of each of the first bonding pad BP1 and the second bonding pad BP2 may protrude further in a horizontal direction toward the second region R2 than, respectively, one side of each of the first source plate 130 and the second source plate 136. The second bonding pad BP2 may be electrically connected to the second source plate 136 through the third bonding contact BC3. The second bonding pad BP2 may be bonded to the first bonding pad BP1 of the first wafer CELL1. The first and second source plates 130 and 136 may be electrically connected through the first and second bonding pads BP1 and BP2. The first and second wafers CELL1 and CELL2 may form a common source potential. The ninth and tenth bonding pads BP9 and BP10 may be formed in the same layer as the second bonding pad BP2 and may be disposed in the second region R2. The ninth bonding pad BP9 may be connected to the tenth bonding contact BC10. The ninth bonding pad BP9 may be connected to the second memory cell array 138 through the tenth bonding contact BC10, the third through-via V3, and the second bit line BL2. The tenth bonding pad BP10 may be connected to the eleventh bonding contact BC11. The tenth bonding pad BP10 may be connected to the second wiring 142 through the eleventh bonding contact BC11 and the fifth through-via V5. In some embodiments, the second wiring 142 on the fifth through-via V5 may serve as a terminal for receiving control signals from outside to control the memory device 100. The tenth bonding pad BP10 may be electrically connected to the outside through the fifth through-via V5 and the second wiring 142.

An upper insulating layer 143 may be disposed on the second bit line BL2, the second wiring 142, and the ninth insulating layer 141. The upper insulating layer 143 may cover the upper surfaces of the second bit line BL2, the second wiring 142, and the ninth insulating layer 141. Through the upper insulating layer 143, the second bit line BL2 and the second wiring 142 may be electrically insulated from the outside. The upper insulating layer 143 may include a nitride.

In some embodiments, a portion of the upper insulating layer 143 may be selectively removed through a photolithography and etching process to form an opening, and the second wiring 142 may be electrically connected to an external circuit through the opening. For example, the opening may be formed for the purpose of making a connection for external input/output interface. The opened region may be connected to an upper package structure through a metal layer, solder bump, or wire bonding.

A third wafer CELL3 may include a substrate 110, a peripheral circuit layer 116, first to fourth peripheral bonding contacts PBC1 to PBC4, first to fourth peripheral bonding pads PBD1 to PBD4, and a peripheral bonding insulating layer 118. Additionally, the third wafer CELL3 may include a peripheral insulating layer 117 surrounding the first to fourth peripheral bonding contacts PBC1 to PBC4.

The substrate 110 may be a silicon substrate, a silicon-germanium (SiGe) substrate, a gallium arsenide (GaAs) substrate, a germanium (Ge) substrate, or a silicon-on-insulator (SOI) substrate.

The peripheral circuit layer 116 may be disposed on the substrate 110. The peripheral circuit layer 116 may include a peripheral circuit 115 that controls operations of memory cells, and a peripheral circuit insulating layer 111 that surrounds the peripheral circuit 115. The peripheral circuit 115 may include a peripheral gate 112, a peripheral contact 113, and a peripheral wiring 114. The peripheral circuit 115 may further include first to fourth peripheral circuit elements 115B, 115C, 115D, and 115A. The first to fourth peripheral circuit elements 115B to 115A may be disposed on the substrate 110. The peripheral circuit insulating layer 111 may be disposed on the substrate 110 and may cover the peripheral circuit 115. This description is by way of example, and it should be understood that the peripheral circuit 115 may include other circuit elements.

The peripheral insulating layer 117 may be disposed on the peripheral circuit layer 116. The peripheral insulating layer 117 may cover the upper surface of the peripheral circuit layer 116. The first to fourth peripheral bonding contacts PBC1 to PBC4 may vertically penetrate the peripheral insulating layer 117 and may be disposed in the first region R1 or the second region R2.

A peripheral bonding insulating layer 118 may be disposed on the peripheral insulating layer 117 and on the first to fourth peripheral bonding contacts PBC1 to PBC4. The peripheral bonding insulating layer 118 may cover the upper surface of the peripheral insulating layer 117 and top portions of the peripheral bonding contacts PBC1 to PBC4. The first to fourth peripheral bonding pads PBD1 to PBD4 may be disposed in the first region R1 or the second region R2.

The fourth peripheral circuit element 115A may be disposed below the first peripheral bonding pad PBD1 and in the first region R1. A first peripheral bonding contact PBC1 may be disposed between the first peripheral bonding pad PBD1 and the fourth peripheral circuit element 115A. The first peripheral bonding pad PBD1 may be bonded to the eighth bonding pad BP8 of the first wafer CELL1. The fourth peripheral circuit element 115A may be electrically connected to the first memory cell array 128 through the first peripheral bonding pad PBD1, the eighth bonding pad BP8, and the first bit line BL1. The fourth peripheral circuit element 115A may provide signals for controlling the first memory cell array 128.

The first peripheral circuit element 115B may be disposed below the second peripheral bonding pad PBD2 and in the second region R2. A second peripheral bonding contact PBC2 may be disposed between the second peripheral bonding pad PBD2 and the first peripheral circuit element 115B. The second peripheral bonding pad PBD2 may be bonded to the third bonding pad BP3. The first peripheral circuit element 115B may be electrically connected to the first and second source plates 130 and 136 through the first through-via V1 and the first and second bonding pads BP1 and BP2. The first peripheral circuit element 115B may supply a source potential to the first and second source plates 130 and 136.

The second peripheral circuit element 115C may be disposed below the third peripheral bonding pad PBD3 and in the second region R2. A third peripheral bonding contact PBC3 may be disposed between the third peripheral bonding pad PBD3 and the second peripheral circuit element 115C. The third peripheral bonding pad PBD3 may be bonded to the fifth bonding pad BP5. The second peripheral circuit element 115C may be electrically connected to the second memory cell array 138 through the second and third through-vias V2 and V3 and the second bit line BL2. The second peripheral circuit element 115C may provide signals for controlling the second memory cell array 138.

The third peripheral circuit element 115D may be disposed below the fourth peripheral bonding pad PBD4 and in the second region R2. A fourth peripheral bonding contact PBC4 may be disposed between the fourth peripheral bonding pad PBD4 and the third peripheral circuit element 115D. The fourth peripheral bonding pad PBD4 may be bonded to the fourth bonding pad BP4. The third peripheral circuit element 115D may be electrically connected to the second wiring 142 through the fourth and fifth through-vias V4 and V5. The third peripheral circuit element 115D may receive control signals applied from an external system through the second wiring 142. Based on the external control signals, the third peripheral circuit element 115D may operate as an interface circuit that controls the overall operating environment of the memory device 100 by converting the external control signals into signal formats suitable for internal operations or generating mode switching signals required for changing operational modes.

The first wafer CELL1 may be bonded onto the third wafer CELL3. At the bonding interface, the first peripheral bonding pad PBD1 may be bonded to the eighth bonding pad BP8, the second peripheral bonding pad PBD2 may be bonded to the third bonding pad BP3, the third peripheral bonding pad PBD3 may be bonded to the fifth bonding pad BP5, and the fourth peripheral bonding pad PBD4 may be bonded to the fourth bonding pad BP4. Simultaneously, the peripheral bonding insulating layer 118 and the third bonding insulating layer 121 may be bonded to form the bonding interface.

The second wafer CELL2 may be bonded onto the first wafer CELL1. At the bonding interface, the first bonding pad BP1 may be bonded to the second bonding pad BP2, the ninth bonding pad BP9 may be bonded to the sixth bonding pad BP6, the tenth bonding pad BP10 may be bonded to the seventh bonding pad BP7, and the second bonding insulating layer 133 may be bonded to the first bonding insulating layer 132.

The first and second wafers CELL1 and CELL2 may be cell wafers, and the third wafer CELL3 may be a peripheral wafer including a peripheral circuit for controlling the cell wafers. The memory device 100 may be fabricated as a module including only the first and second wafers CELL1 and CELL2 without the third wafer CELL3.

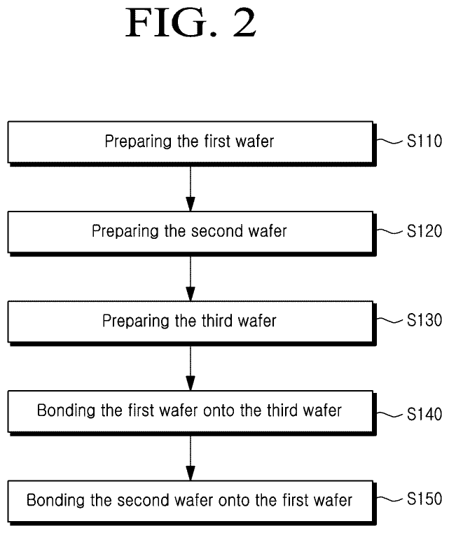

FIG. 2 is a flowchart illustrating a method of manufacturing a semiconductor device according to an embodiment of the present disclosure.

Referring to FIG. 2, the method of manufacturing a semiconductor device may include preparing the first wafer CELL1 (S110), preparing the second wafer CELL2 (S120), preparing the third wafer CELL3 (S130), bonding the first wafer CELL1 onto the third wafer CELL3 (S140), and bonding the second wafer CELL2 onto the first wafer CELL1 (S150).

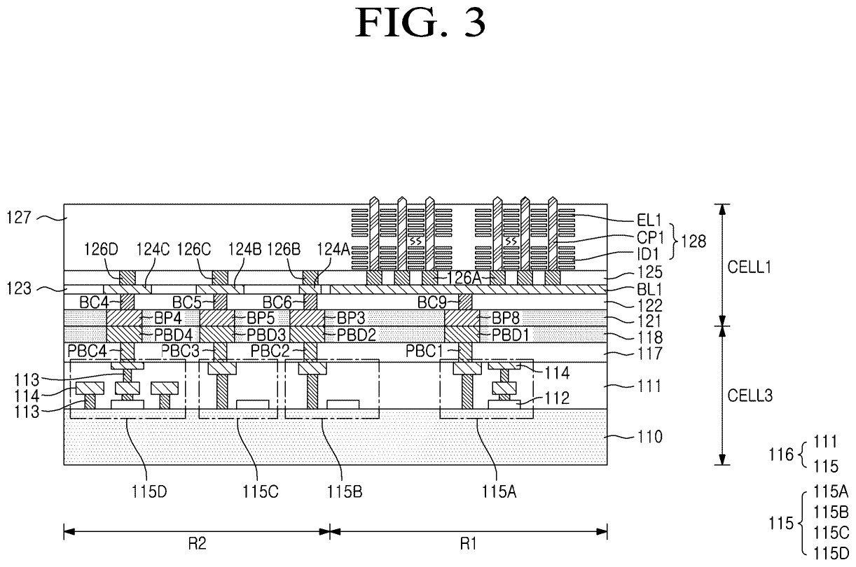

FIG. 3 to FIG. 9 are cross-sectional views illustrating a semiconductor device in sequential process steps according to an embodiment of the present disclosure. FIG. 3-8 illustrate intermediate steps of forming the first wafer CELL1.

Referring to FIG. 3, a third wafer CELL3 including a peripheral circuit 115, first to fourth peripheral bonding contacts PBC1 to PBC4, first to fourth peripheral bonding pads PBD1 to PBD4, and a peripheral bonding insulating layer 118 may be provided on a substrate 110. The peripheral circuit 115 including a peripheral gate 112, a peripheral contact 113, and a peripheral wiring 114 may be formed on the substrate 110. The peripheral circuit 115 may include first to fourth peripheral circuit elements 115B, 115C, 115D, and 115A. The first to fourth peripheral bonding contacts PBC1 to PBC4 may vertically penetrate the peripheral insulating layer 117 and may be formed on the first to fourth peripheral circuit elements, respectively. The first to fourth peripheral bonding pads PBD1 to PBD4 may be respectively formed on the peripheral bonding contacts PBC1 to PBC4. Accordingly, the third wafer CELL3 is formed.

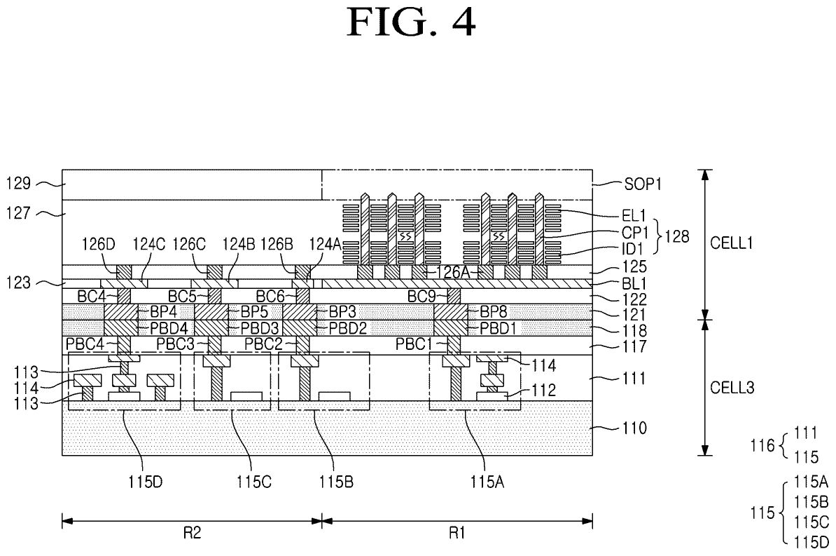

Referring to FIG. 4, a first wafer CELL1, which includes third, fourth, fifth, and eighth bonding pads BP3, BP4, BP5, and BP8; a third bonding insulating layer 121; fourth, fifth, sixth, and ninth bonding contacts BC4, BC5, BC6, and BC9; first wirings 124A to 124C; first contacts 126A to 126D; a first memory cell array 128; and a first insulating layer 127, may be provided on the third wafer CELL3. The first wafer CELL1 may be bonded onto the third wafer CELL3. At the bonding interface, the first periphery bonding pad PBD1 and the eighth bonding pad BP8, the second periphery bonding pad PBD2 and the third bonding pad BP3, the third periphery bonding pad PBD3 and the fifth bonding pad BP5, the fourth periphery bonding pad PBD4 and the fourth bonding pad BP4, and the periphery bonding insulating layer 118 and the third bonding insulating layer 121 may each be bonded together.

The eighth bonding pad BP8 may be formed on the first peripheral bonding pad PBD1. The third bonding pad BP3 may be formed on the second peripheral bonding pad PBD2. The fifth bonding pad BP5 may be formed on the third peripheral bonding pad PBD3. The fourth bonding pad BP4 may be formed on the fourth peripheral bonding pad PBD4. The ninth bonding contact BC9 may vertically penetrate the fourth insulating layer 122 and may be formed on the eighth bonding pad BP8. The sixth bonding contact BC6 may vertically penetrate the fourth insulating layer 122 and may be formed on the third bonding pad BP3. The fifth bonding contact BC5 may vertically penetrate the fourth insulating layer 122 and may be formed on the fifth bonding pad BP5. The fourth bonding contact BC4 may vertically penetrate the fourth insulating layer 122 and may be formed on the fourth bonding pad BP4. The first bit line BL1 may be formed on the ninth bonding contact BC9. The plurality of first wirings 124A to 124C may be respectively formed on the third to fifth bonding contacts BC3 to BC5. The first contacts 126A may vertically penetrate the second insulating layer 125 and may be formed on the first bit line BL1. Other first contacts 126B, 126C, and 126D may vertically penetrate the second insulating layer 125 and may be respectively formed on the first wirings 124A to 124C. The first memory cell array 128 may be formed on the first contacts 126A formed in the first region R1. The first memory cell array 128 may include a plurality of first cell plugs CP1 formed in a vertical direction, a plurality of first electrode layers EL1 alternately stacked along the first cell plugs CP1, and a plurality of first interlayer insulating layers ID1. A chemical mechanical polishing/planarization (CMP) process and cleaning process may be performed so that the first cell plugs CP1 of the first memory cell array 128 are exposed at the top of the first wafer CELL1.

A fifth insulating layer 129 may be formed on the first memory cell array 128. A source plate opening SOP1 may be formed by selectively removing the fifth insulating layer 129 in the first region R1 through photolithography and etching processes.

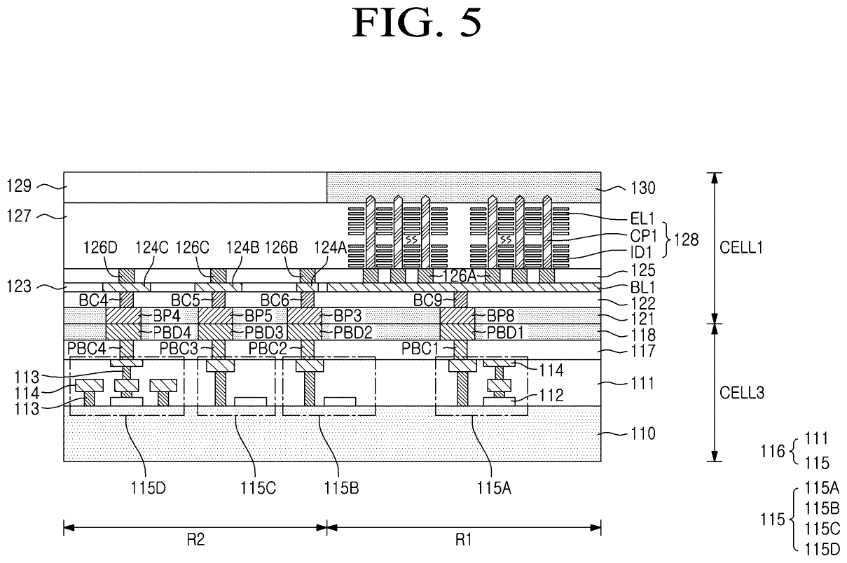

Referring to FIG. 5, a first source plate 130 may be formed by depositing source polysilicon into the source plate opening SOP1 (see FIG. 4). After forming the first source plate 130, its upper surface may be planarized by the CMP process.

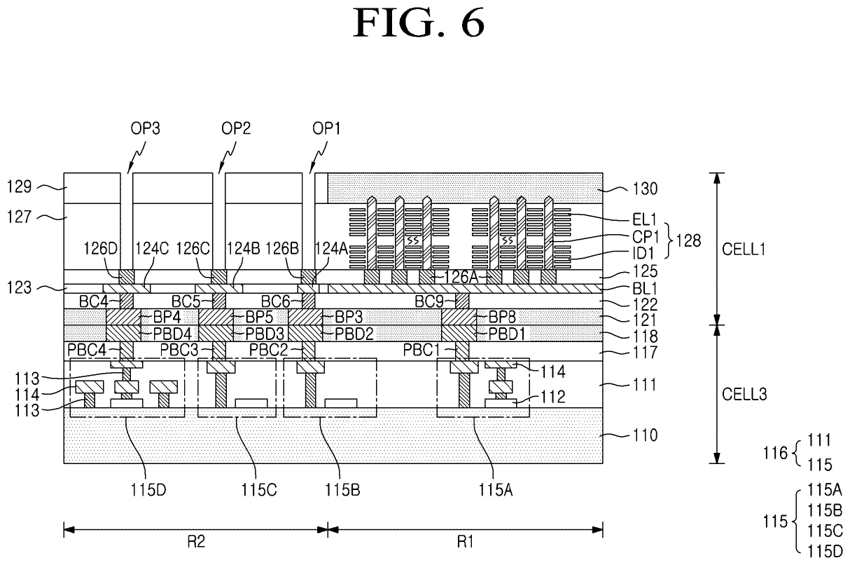

Referring to FIG. 6, first to third openings OP1 to OP3 may be formed by vertically etching through the first insulating layer 127 and the fifth insulating layer 129. These openings may be formed by performing a photolithography and etching process on the first insulating layer 127 and the fifth insulating layer 129 so that an upper portion of the first contact 126 is exposed.

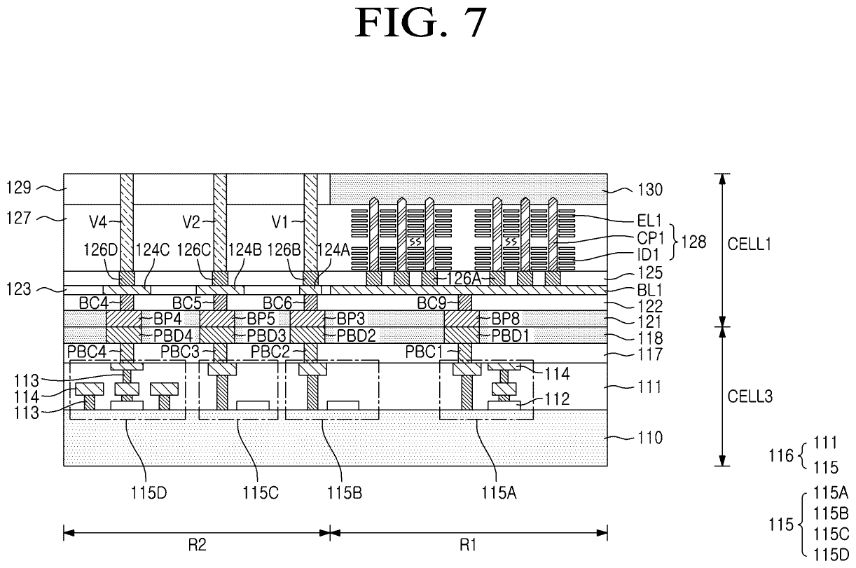

Referring to FIG. 7, first, second, and fourth through-vias V1, V2, and V4 may be formed by depositing a metal in the first to third openings OP1 to OP3 (see FIG. 6). The metal for forming the through-vias may be tungsten (W) or titanium nitride (TiN). Although not illustrated, a barrier metal may be formed surrounding the through-vias V1, V2, and V4. The barrier metal of the through-via may include titanium nitride (TiN) or tungsten nitride (WN).

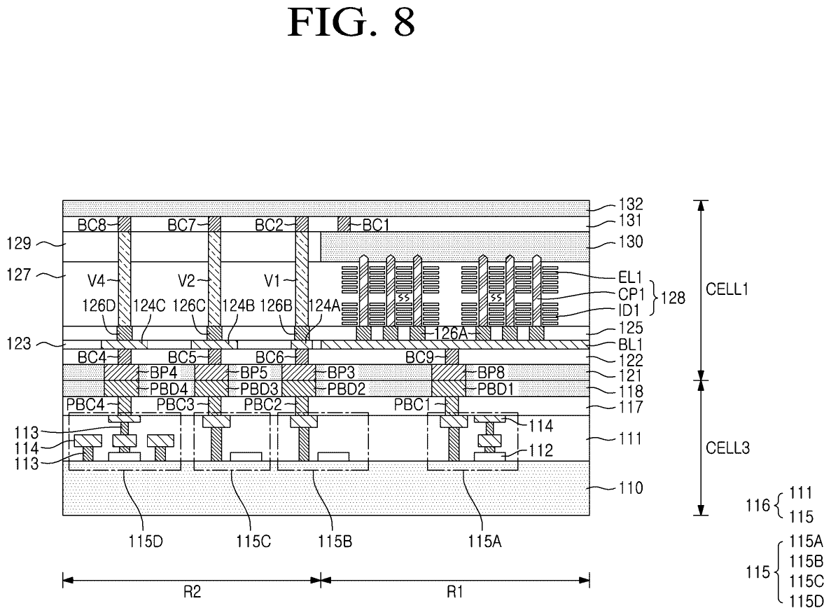

Referring to FIG. 8, a sixth insulating layer 131 may be formed over the fifth insulating layer 129, the first, second, and fourth through-vias V1, V2, and V4, and the first source plate 130. The sixth insulating layer 131 may be patterned to expose upper portions of the first, second, and fourth through-vias V1, V2, and V4, as well as a portion of the top surface of the first source plate 130. First, second, seventh, and eighth bonding contacts BC1, BC2, BC7, and BC8 may be formed by electroplating metal into the opened sixth insulating layer 131, followed by the CMP process. The first bonding contact BC1 may be formed on the first source plate 130. The second bonding contact BC2 may be formed on the first through-via V1. The seventh bonding contact BC7 may be formed on the second through-via V2. The eighth bonding contact BC8 may be formed on the fourth through-via V4. The first bonding insulating layer 132 may be formed over the sixth insulating layer 131 and the first, second, seventh, and eighth bonding contacts BC1, BC2, BC7, and BC8.

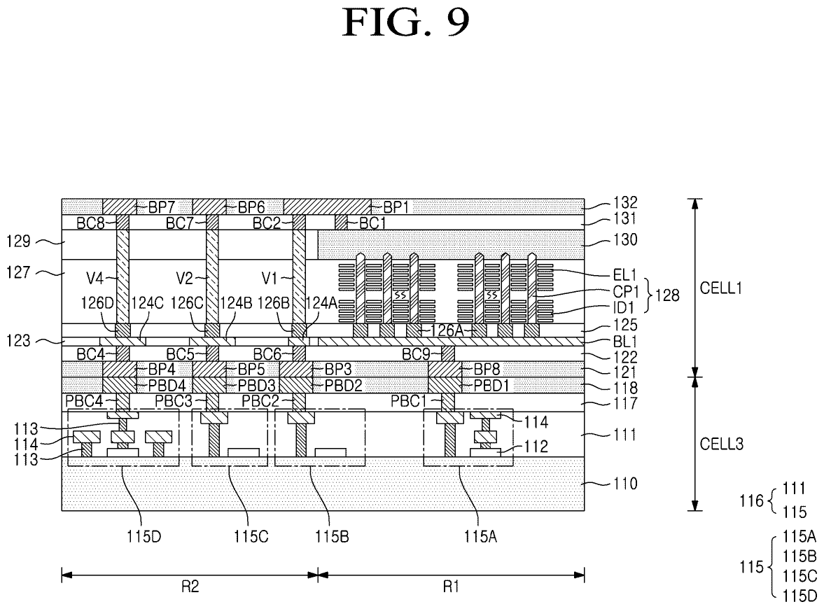

Referring to FIG. 9, first, sixth, and seventh bonding pads BP1, BP6, and BP7 may be formed over the first, second, seventh, and eighth bonding contacts BC1, BC2, BC7, and BC8. The first bonding pad BP1 may be formed to extend horizontally from a first region R1 to one side of a second region R2, and may contact both the first and second bonding contacts BC1 and BC2. The sixth bonding pad BP6 may be formed on the seventh bonding contact BC7. The seventh bonding pad BP7 may be formed on the eighth bonding contact BC8. The first bonding insulating layer 132 may be opened through a photolithography and etching process to expose the upper surfaces of the first, second, seventh, and eighth bonding contacts BC1, BC2, BC7, and BC8, as well as the upper surface of the sixth insulating layer 131 around the bonding contacts. The first, sixth, and seventh bonding pads BP1, BP6, and BP7 may be formed by electroplating metal into the opened first bonding insulating layer 132, followed by a CMP process. Through these processes, the first wafer CELL1 may be formed.

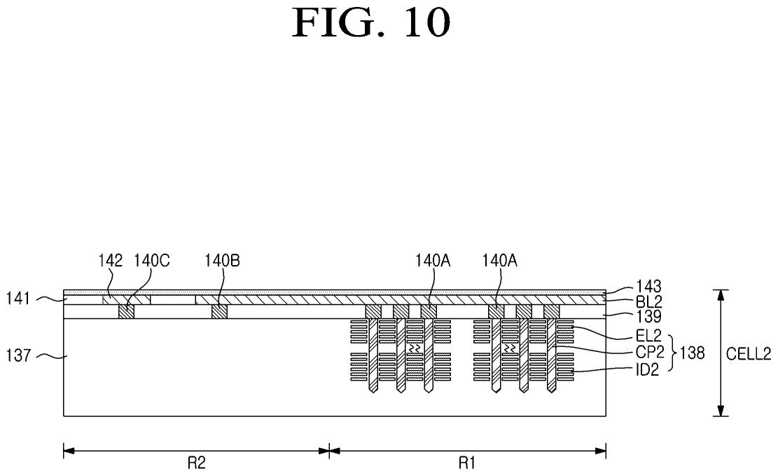

FIGS. 10-17 illustrate intermediate steps of forming the second wafer CELL2. Referring to FIG. 10, a second wafer CELL2 including a second memory cell array 138 and a seventh insulating layer 137 surrounding the second memory cell array 138 may be provided. The second memory cell array 138 may include a plurality of second cell plugs CP2 formed in a vertical direction, a plurality of second electrode layers EL2 alternately stacked along the second cell plugs CP2, and a plurality of second interlayer insulating layers ID2. The second wafer CELL2 may further include second contacts 140A to 140C and an eighth insulating layer 139 formed over the second memory cell array 138 and the seventh insulating layer 137. In the first region R1, the second contacts 140A may vertically penetrate the eighth insulating layer 139 and be formed on the second cell plugs CP2. In the second region R2, the second contacts 140B and 140C may vertically penetrate the eighth insulating layer 139 and be formed on the seventh insulating layer 137. The second wafer CELL2 may further include a second bit line BL2, a second wiring 142, and a ninth insulating layer 141 disposed over the second contacts 140A to 140C and the eighth insulating layer 139. The second bit line BL2 may be formed over the second contacts 140A and 140B. The second wiring 142 may be formed over the second contact 140C and the eighth insulating layer 139 around the second contact 140C. The second bit line BL2 on the second memory cell array 138 may be formed to extend horizontally from the first region R1 to the middle of the second region R2. The second wafer CELL2 may further include an upper insulating layer 143 over the second bit line BL2, the second wiring 142, and the ninth insulating layer 141. The upper insulating layer 143 may cover the upper surfaces of the second bit line BL2, the second wiring 142, and the ninth insulating layer 141 and provide insulation from the outside. The upper insulating layer 143 may include a nitride.

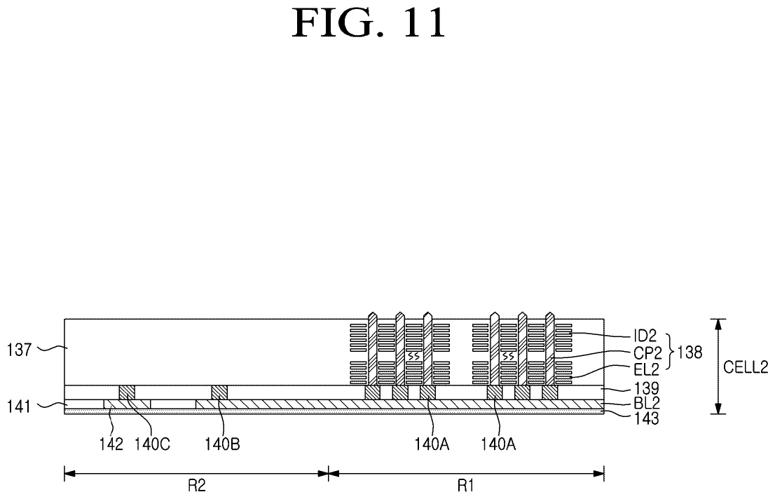

Referring to FIG. 11, the second wafer CELL2 including the second memory cell array 138 may be flipped vertically by 180 degrees and the second cell plugs CP2 may be exposed through CMP and etching processes.

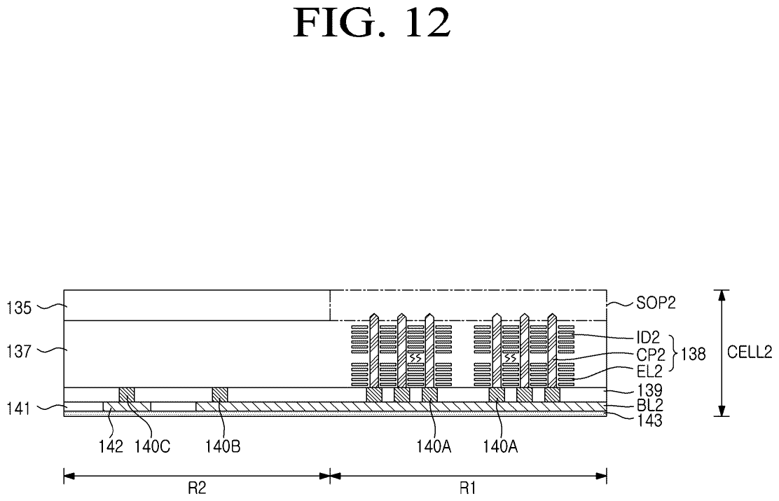

Referring to FIG. 12, a tenth insulating layer 135 may be formed on the second memory cell array 138. A second source plate opening SOP2 may be formed by removing the tenth insulating layer 135 in the first region R1 through photolithography and etching.

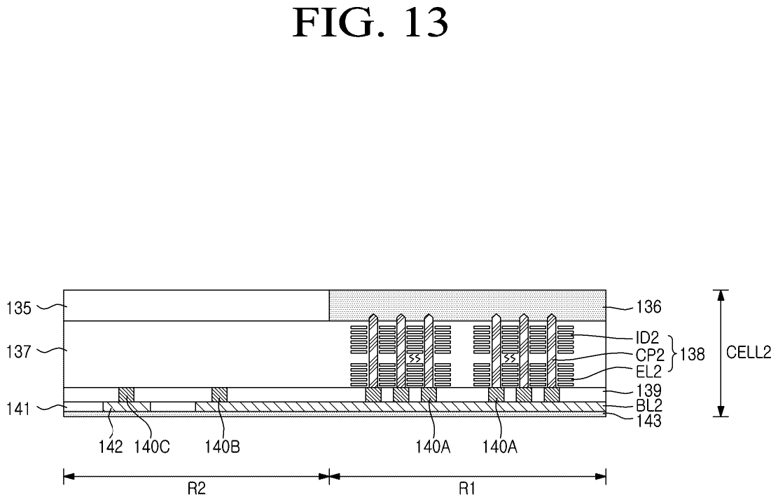

Referring to FIG. 13, a second source plate 136 may be formed by depositing source polysilicon in the source plate opening SOP2 (see FIG. 12). After forming the second source plate 136, its upper surface may be planarized through a CMP process.

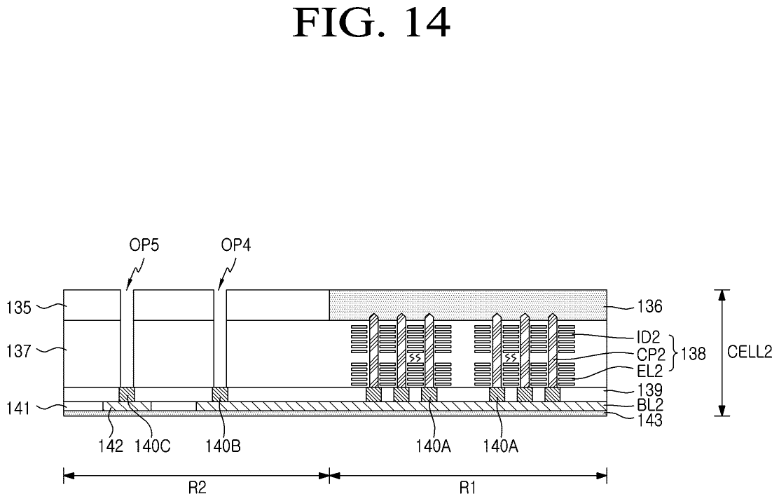

Referring to FIG. 14, fourth and fifth openings OP4 and OP5 may be formed by vertically etching through the seventh insulating layer 137 and the tenth insulating layer 135. These openings may be formed through photolithography and etching to expose the upper surfaces of the second contacts 140.

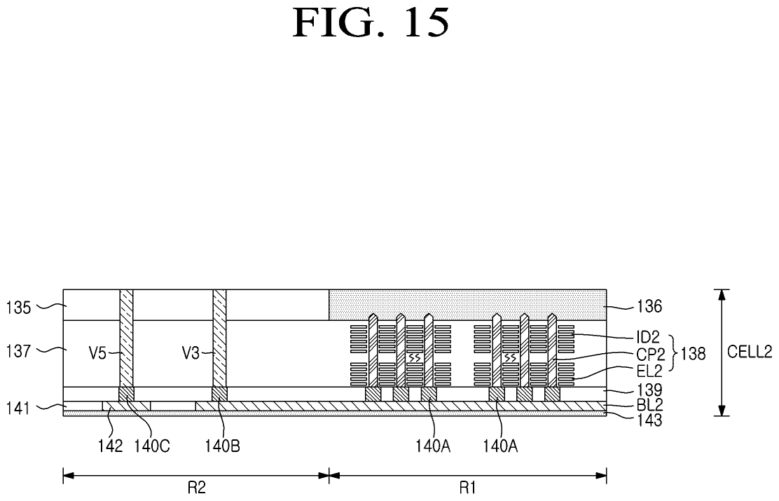

Referring to FIG. 15, third and fifth through-vias V3 and V5 may be formed by depositing metal in the fourth and fifth openings OP4 and OP5 (see FIG. 14). Although not shown, a barrier metal may be formed surrounding the through-vias V3 and V5.

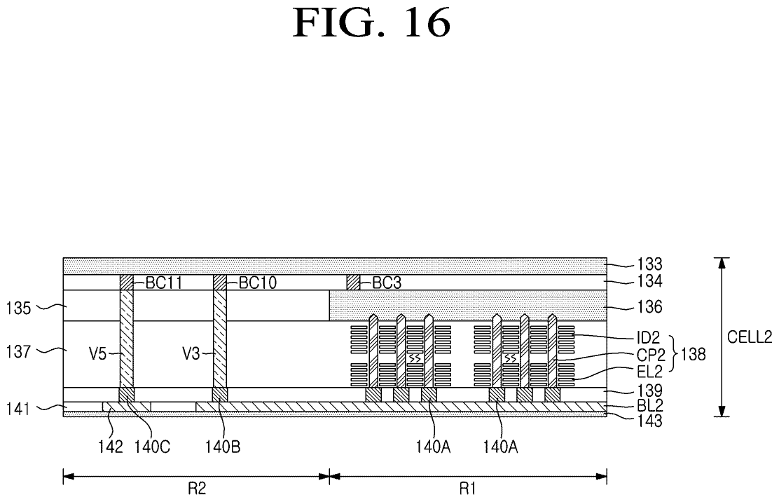

Referring to FIG. 16, the eleventh insulating layer 134 may be formed on the tenth insulating layer 135, the third and fifth through-vias V3 and V5, and the second source plate 136. Upper ends of the third and fifth through-vias V3 and V5 and an upper surface portion of the second source plate 136 may be exposed through the eleventh insulating layer 134. The third, tenth, and eleventh bonding contacts BC3, BC10, and BC11 may be formed by plating metal into the openings of the eleventh insulating layer 134 and subsequently performing a CMP process. The third bonding contact BC3 may be formed on the second source plate 136. The tenth bonding contact BC10 may be formed on the third through-via V3. The eleventh bonding contact BC11 may be formed on the fifth through-via V5. The second bonding insulating layer 133 may be formed on the eleventh insulating layer 134 and the third, tenth, and eleventh bonding contacts BC3, BC10, and BC11.

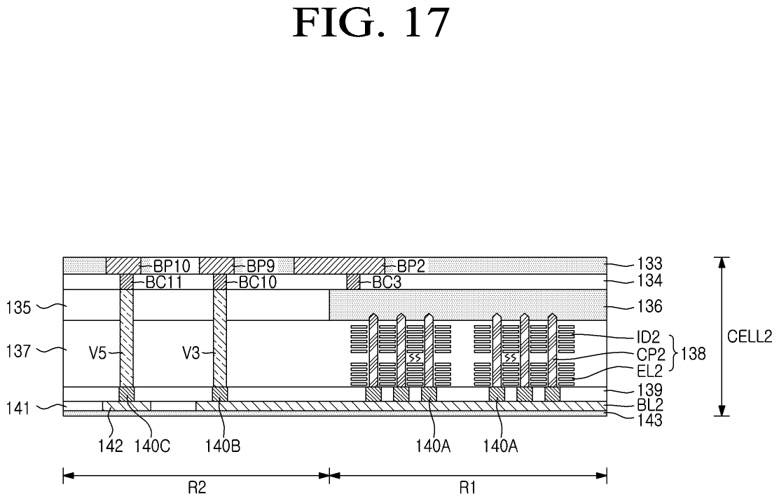

Referring to FIG. 17, the second bonding pad BP2 may be formed on the third bonding contact BC3. The second bonding pad BP2 may extend horizontally from the first region R1 to one side of the second region R2. The ninth bonding pad BP9 may be formed on the tenth bonding contact BC10. The tenth bonding pad BP10 may be formed on the eleventh bonding contact BC11. The second bonding insulating layer 133 may be patterned through a photolithography and etching process such that an upper surface of the third bonding contact BC3 and an upper surface of the eleventh insulating layer 134 around the third bonding contact BC3 are exposed. The second bonding insulating layer 133 may also be patterned such that upper surfaces of the tenth and eleventh bonding contacts BC10 and BC11, as well as the upper surface of the eleventh insulating layer 134 around the tenth and eleventh bonding contacts BC10 and BC11, are exposed. The second, ninth, and tenth bonding pads BP2, BP9, and BP10 may be formed by electroplating metal into the openings of the second bonding insulating layer 133, followed by a CMP process. In this manner, the second wafer CELL2 may be formed.

Referring again to FIG. 1, the second wafer CELL2 formed through the processes described in FIG. 10 to FIG. 17 may be bonded to the first wafer CELL1. At the bonding interface, the first and second bonding pads BP1 and BP2 may be bonded. At the bonding interface, the sixth and ninth bonding pads BP6 and BP9 may be bonded, and the seventh and tenth bonding pads BP7 and BP10 may be bonded. The first bonding insulating layer 132 and the second bonding insulating layer 133 may also be bonded. Each of the insulating and metal layers of the first and second wafers CELL1 and CELL2 may be simultaneously bonded to form a direct or hybrid bonding interface.

According to embodiments of the present disclosure, the memory cell array is distributed across two cell wafers, which allows the number of word line stacks required in each cell wafer to be reduced by half. As a result, the depth of cell plugs and through-vias within each individual wafer can be kept shallow. In particular, defects such as punch/open failures caused by tilt, rotation, or subloss during etching—issues that arise as plug depth increases—can be effectively mitigated.

Furthermore, according to an embodiment of the present disclosure, the memory device may have a structure in which source plates of the respective cell wafers are electrically connected through bonding pads. In the peripheral wafer, a source potential may be supplied to the source plate of the wafer closest to the peripheral wafer among the wafers stacked thereon, so that the source potential may be provided to the source plates of all the cell wafers. Accordingly, there is no need to additionally form separate deep through-vias in the peripheral wafer for supplying the source potential to all the wafers. As a result, the manufacturing process of the memory device may be simplified, and process yield and reliability may be improved.

Although various embodiments of the disclosed technology have been described with particular specifics and varying details for illustrative purposes, those skilled in the art will appreciate that various modifications, additions and substitutions may be made based on what is disclosed or illustrated in the present disclosure without departing from the spirit and scope of the invention as defined in the following claims.

What is claimed is:

1. A memory device comprising:
a first wafer including a first source plate, a first memory cell array disposed below the first source plate, and a first bonding pad connected to the first source plate;
a second wafer bonded on the first wafer, and including a second source plate, a second memory cell array disposed on the second source plate, and a second bonding pad connected to the second source plate and bonded to the first bonding pad; and
a third wafer including a peripheral circuit configured to control at least one of the first wafer and the second wafer.

2. The memory device of claim 1,
wherein the first wafer and the second wafer include a first region and a second region adjacent to one side of the first region, and
wherein one side of each of the first bonding pad and the second bonding pad protrudes further in a horizontal direction toward the second region than, respectively, one side of each of the first source plate and the second source plate.

3. The memory device of claim 1,
wherein the peripheral circuit includes a first peripheral circuit element, and
wherein the first wafer includes a first through-via connecting the first bonding pad to the first peripheral circuit element.

4. The memory device of claim 3,
wherein the peripheral circuit further includes a second peripheral circuit element,
wherein the first wafer includes a second through-via connected to the second peripheral circuit element, and
wherein the second wafer includes a third through-via connecting the second memory cell array to the second through-via.

5. The memory device of claim 4,
wherein the peripheral circuit further includes a third peripheral circuit element,
wherein the first wafer includes a fourth through-via connected to the third peripheral circuit element, and
wherein the second wafer includes a fifth through-via connected to the fourth through-via.

6. The memory device of claim 3,
wherein the first wafer includes a first bonding contact connected to the first source plate and a second bonding contact connected to the first through-via, and
wherein the second wafer includes a third bonding contact connected to the second source plate.

7. The memory device of claim 6,
wherein the first wafer includes a first region and a second region, and
wherein the first bonding pad extends horizontally from the first region to the second region to be in contact with the first bonding contact and the second bonding contact.

8. The memory device of claim 3,
wherein the first wafer includes a first region and a second region, and
wherein the first through-via is spaced apart from the first source plate in a horizontal direction and disposed in the second region.

9. The memory device of claim 3,
wherein the first wafer includes a third bonding pad disposed below the first through-via, and
wherein widths of the first bonding pad and the second bonding pad are greater than a width of the third bonding pad.

10. The memory device of claim 1,
wherein the first wafer includes a first bonding insulating layer surrounding the first bonding pad,
wherein the second wafer includes a second bonding insulating layer surrounding the second bonding pad, and
wherein, at a bonding interface between the first wafer and the second wafer, the first bonding pad is bonded to the second bonding pad, and the first bonding insulating layer is bonded to the second bonding insulating layer.

11. A memory device comprising:
a first wafer including a first source plate, a first memory cell array disposed below the first source plate, and a first bonding pad connected to the first source plate; and
a second wafer bonded on the first wafer, and including a second source plate, a second memory cell array disposed on the second source plate, and a second bonding pad connected to the second source plate and bonded to the first bonding pad.

12. The memory device of claim 11,
wherein the first wafer includes a first through-via connected to the first bonding pad, a first bonding contact connected to the first source plate, and a second bonding contact connected to the first through-via, and
wherein the second wafer includes a third bonding contact connected to the second source plate.

13. The memory device of claim 12,
wherein the first wafer includes a first region and a second region, and
wherein the first bonding pad extends horizontally from the first region to the second region to be in contact with the first bonding contact and the second bonding contact.

14. The memory device of claim 13,
wherein the first wafer includes a second through-via connected to the second memory cell array, and
wherein the second wafer includes a third through-via connecting the second through-via to the second memory cell array.

15. The memory device of claim 13,
wherein the first wafer includes a first region and a second region, and
wherein the first through-via is spaced apart from the first source plate in a horizontal direction and disposed in the second region.

16. The memory device of claim 13,
wherein the first wafer includes a third bonding pad disposed below the first through-via, and
wherein widths of the first bonding pad and the second bonding pad are greater than a width of the third bonding pad.

17. The memory device of claim 11,
wherein the first wafer includes a first bonding insulating layer surrounding the first bonding pad,
wherein the second wafer includes a second bonding insulating layer surrounding the second bonding pad, and
wherein, at a bonding interface between the first wafer and the second wafer, the first bonding pad is bonded to the second bonding pad, and the first bonding insulating layer is bonded to the second bonding insulating layer.

18. The memory device of claim 17,
wherein each of the first bonding insulating layer and the second bonding insulating layer includes a nitride layer.

19. A memory device comprising:
a first wafer including a first source plate, a first bonding pad disposed on the first source plate and electrically connected thereto, and a first through-via below the first bonding pad; and
a second wafer bonded on the first wafer, and including a second source plate, and a second bonding pad electrically connected to the second source plate and bonded to the first bonding pad.

20. The memory device of claim 19,
wherein the first wafer and the second wafer include a first region and a second region,
wherein the first through-via is spaced apart from the first source plate in a horizontal direction and disposed in the second region,
wherein the first wafer further includes a third bonding pad below the first through-via, and
wherein the first bonding pad, the first through-via, and the third bonding pad are electrically connected.
